(19) United States
(12) Patent Application Publication
(10) Pub. No.: US 2015/0311161 A1
(43) Pub. Date: Oct. 29, 2015

(54) SELECTIVE PLATING WITHOUT PHOTORESIST

(71) Applicant: International Business Machines Corporation, Armonk, NY (US)

(72) Inventors: Charles L. Arvin, Savannah, GA (US); Harry D. Cox, Rifton, NY (US); Brian M. Erwin, Lagrangeville, NY (US); John J. Garant, Poughkeepsie, NY (US); Ekta Misra, Carmel, NY (US); Nicholas A. Polomoff, White Plains, NY (US); Jennifer D. Schuler, Poughquag, NY (US)

(73) Assignee: International Business Machines Corporation, Armonk, NY (US)

(21) Appl. No.: 14/263,423

(22) Filed: Apr. 28, 2014

(51) Int. Cl. H01L 23/532; H01L 21/321; H01L 21/288; H01L 23/528; H01L 21/768

(52) U.S. Cl. CPC H01L 23/53238; H01L 23/528; H01L 23/53233; H01L 21/76846; H01L 21/76879; H01L 21/2885; H01L 21/3212

(57) ABSTRACT

A method including forming a stack of layers on top of a dielectric layer and within an opening in the dielectric layer, the stack of layers comprising a first layer, a second layer, a third layer, and a fourth layer, each formed successively one on top of another, removing a first portion of the fourth layer outside the opening to expose a portion of the third layer, a second portion of the fourth layer remains within the opening, filling the opening with a metal by applying an electrical potential to the second layer during an electroplating technique in which the metal plates out on the fourth layer but does not plate out on the third layer, and removing portions of the first layer, the second layer, and the third layer to expose an upper surface of the dielectric layer between the opening and an adjacent opening.

### BACKGROUND

The present invention generally relates to semiconductor fabrication, and more particularly to a multilayered plating structure to facilitate selective electroplating of conductive features.

Electroplating is a widely used process in semiconductor fabrication. Electroplating techniques require a cathode. Generally, the part to be plated can act as the cathode. The cathode can be connected to a negative terminal of an external power supply and thus must be electrically conductive. In order to electroplate into an opening, a trench or via hole etched in a nonconductive material, a seed layer is required to act as the cathode. For example, a copper film may be deposited using physical vapor deposition or other known deposition techniques to form the requisite cathode, or seed layer, in preparation for electroplating. When electroplating into the opening an electrical potential is applied to the copper seed layer while the structure is exposed to an electrolyte solution where the desired plating material can plate out onto the cathode.

Typically, the seed layer may serve two functions, (1) to provide electrical current to facilitate the electroplating process and (2) to provide a “seed” or foundation to which a conductive material can plate. In most cases the conductive material is desired only within the opening, and a variety of techniques exist to either limit the electroplating to only the opening, or alternatively to remove excess conductive material after the electroplating technique.

One technique may include patterning a mask above the seed layer to obstruct all areas but the opening, therefore allowing the conductive material to plate only on the seed layer within the opening. Another technique may include plating the conductive layer on the entire seed layer, including outside of the opening, and then subsequently removing the excess or overburden material using a polishing technique.

### SUMMARY

According to one embodiment of the present invention, a method is provided. The method may include forming a stack of layers on top of a dielectric layer and within an opening in the dielectric layer, the stack of layers comprising a first layer, a second layer, a third layer, and a fourth layer, each formed successively one on top of another, removing a first portion of the fourth layer outside the opening to expose a portion of the third layer, a second portion of the fourth layer remains within the opening, filling the opening with a metal by applying an electrical potential to the second layer during an electroplating technique in which the metal plates out on the fourth layer but does not plate out on the third layer, and removing portions of the first layer, the second layer, and the third layer to expose an upper surface of the dielectric layer between the opening and an adjacent opening.

According to another embodiment of the present invention, a method is provided. The method may include selectively plating a conductive feature in an opening in a dielectric layer without plating an upper surface of the dielectric layer using a quad layer plating structure including a first layer, a second layer, a third layer, and a fourth layer each formed successively one on top of another, the first layer being in direct contact with the dielectric layer.

According to another embodiment of the present invention, a structure is provided. The structure may include a stack of conformal layers on top of a dielectric layer and within an opening in the dielectric layer, the stack of layers including a first layer, a second layer, a third layer, and a fourth layer, each formed successively one on top of another with the first layer being in direct contact with the dielectric layer, and a conductive feature located directly on top of the fourth layer within the opening.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIGS. 1-6 are a cross-sectional view of a semiconductor structure according to an exemplary embodiment.

FIG. 1 illustrates depositing a stack of layers on top of a dielectric layer and within an opening in the dielectric layer according to an exemplary embodiment.

FIG. 2 illustrates electroplating a conductive feature within the opening and on top of the stack of layers to create a final structure according to an exemplary embodiment.

FIG. 3 illustrates a final structure according to an alternative exemplary embodiment.

FIG. 4 illustrates a final structure according to an alternative exemplary embodiment.

FIG. 5 illustrates a final structure according to an alternative exemplary embodiment.

FIG. 6 illustrates a final structure according to an alternative exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

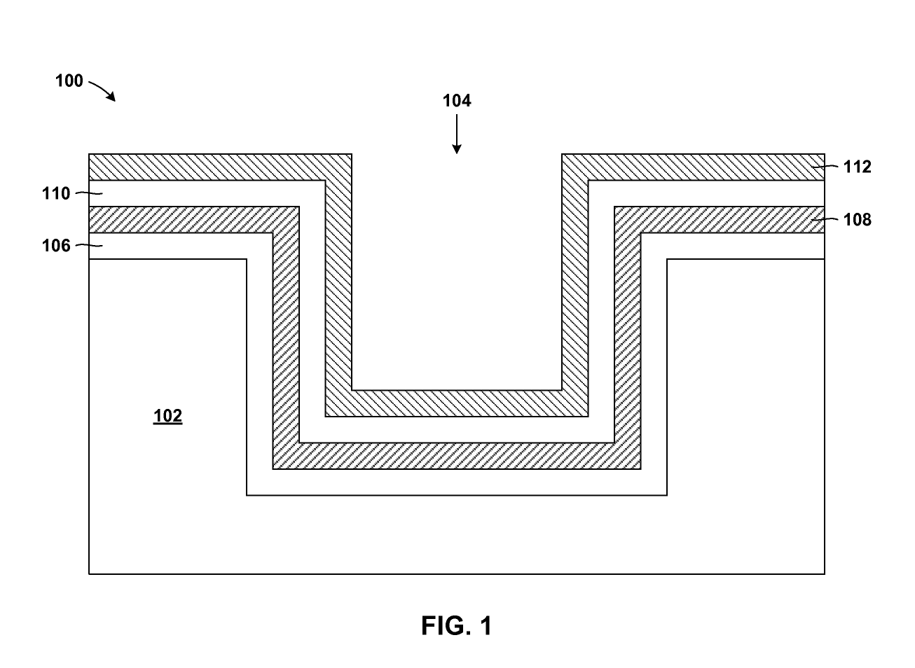

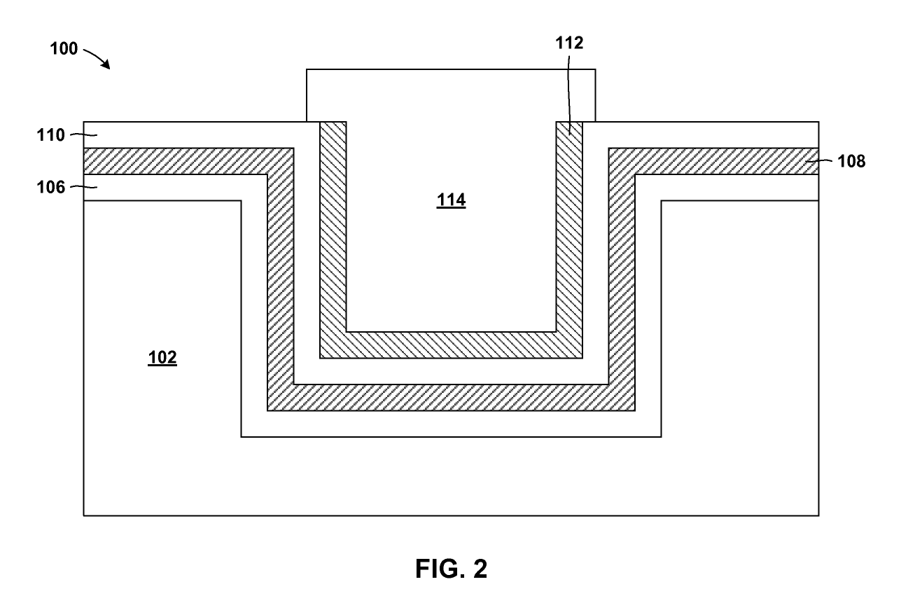

The present invention generally relates to semiconductor fabrication, and more particularly to a multilayered plating structure to facilitate selective electroplating of conductive features. Integrating a multilayered plating structure into the fabrication of a conductive feature may produce good selectivity and enable uniform plating all while minimizing processing defects, lowering fabrication costs, and improving yield. One way to selectively plate a conductive feature using the multilayered plating structure is described in detail below by referring to the accompanying drawings FIGS. 1-2.

FIGS. 1-2 illustrate and describe stages in a fabrication process of a structure 100 in accordance with an embodiment of the invention. Each of the figures is a cross section of a portion of a semiconductor wafer and may illustrate a representative conductive feature for purposes of the following description.

Referring now to FIG. 1, the structure 100 according to an embodiment of the invention is shown. The structure 100 may include a dielectric layer 102. The dielectric layer may include any dielectric layer in a typical semiconductor structure. In an embodiment, the dielectric layer 102 may be included in a back-end-of-line interconnect level. The dielectric layer 102 may include any type of dielectric material used for insulating conductive features known to a person of ordinary skill in the art including, for example, silicon dioxide, silicon nitride, tetraethyl orthosilicate, or polyimide.

The dielectric layer 102 may be formed above a substrate using a conventional deposition process such as, for example, chemical vapor deposition (CVD), plasma-enhanced CVD, evaporation, spin-on coating or other like deposition process. The dielectric layer 102 may have a thickness ranging from about 0.5 μm to about 10 μm. The thickness of the dielectric layer 102 after deposition may vary and is not critical to the various embodiments of the present invention. It should be noted that the dielectric layer 102, while only depicted as a single layer, may include a plurality of layers.

With continued reference to FIG. 1, an opening 104 may be formed in the dielectric layer 102. The opening 104 may be formed in preparation for forming a conductive feature, such as for example, a metal line or metal via. In some cases, the opening 104 may have a depth less than the thickness of the dielectric layer 102, which may typically be used to form a metal line, as illustrated. In other cases, the opening 104 may have a depth equal to or greater than the thickness of the dielectric layer 106, and may typically be used to form a metal via to facilitate an electrical connection between dielectric layers. In such cases where the opening 104 may extend through an entire thickness of the dielectric layer, the opening 104 may be formed above and expose a pre-existing interconnect structure, for example, a metal line in an underlying metal level. As such, the conductive feature subsequently formed in the opening 104 may be in electrical contact with the underlying metal liner. The opening 104 may be formed using any technique known to a person of ordinary skill in the art including, for example, creating a pattern using a standard photoresist process to create the pattern by photolithography and transferring the pattern to the dielectric layer 102 by a reactive ion etch (RIE) technique using a standard fluorine-containing RIE chemistry. Portions of the dielectric layer 102 are subsequently stripped away, to create the opening 104, using standard techniques known to a person of ordinary skill in the art.

Next, a stack of layers may then be conformally deposited on top of the structure 100, and more specifically on top of the dielectric layer 102 and within the opening 104. The stack of layers may alternatively be referred to as a quad layer plating structure. The stack of layers may include a first layer 106, a second layer 108, a third layer 110, and a fourth layer 112. The first layer 106, the second layer 108, the third layer 110, and the fourth layer 112 may each be deposited successively one on top of another. After, depositing the stack of layers, the structure 100 will undergo an electroplating technique used to fill the opening 104 with a conductive interconnect material (hereinafter “interconnect material”), as discussed below with reference to FIG. 2.

The first layer 106 may be deposited on top of the dielectric layer 102 and within the opening 104. It should be noted that the first layer 106, while only depicted as a single layer, may include a plurality of layers. The first layer 106 may include, but is not limited to, tantalum nitride, tantalum, titanium, titanium nitride, tungsten, titanium tungsten, ruthenium, cobalt, or any combination of these materials. In an embodiment, the first layer 106 may include a tantalum nitride layer followed by a tantalum layer or vice versa. In another embodiment, the first layer 106 may include a titanium tungsten layer. The first layer 106 may have a total thickness ranging from about 5 nm to about 500 nm, and ranges there between, although a thickness of the first layer 106 less than 5 nm or greater than 500 nm is acceptable. More typically, the first layer 106 may have a thickness ranging from about 50 nm to about 150 nm.

The first layer 106 may be deposited using any suitable deposition technique known in the art, such as, for example, atomic layer deposition (ALD), molecular layer deposition (MLD), chemical vapor deposition (CVD), in-situ radical assisted deposition, metalorganic chemical vapor deposition (MOCVD), molecular beam epitaxy (MBE), physical vapor deposition (PVD), sputtering, plating, evaporation, ion beam deposition, electron beam deposition, laser assisted deposition, chemical solution deposition, or any combination thereof. In a preferred embodiment, the first layer 106 may be deposited using a sputter deposition technique.

The first layer 106 may serve two purposes, one to provide mechanical adhesion to the dielectric layer 102, and two, to act as a barrier layer. The primary function of the first layer 106 may be to form a mechanical bond between the dielectric layer 102 and a conductive feature subsequently formed within the opening 104. In doing so, the first layer 106 may provide some amount of mechanical adhesion between the dielectric layer 102 and the second layer 108. As a barrier, the first layer 106 may serve to prevent any subsequently formed or deposited conductive material from diffusing into the dielectric layer 102. It should be noted that the first layer 106 may alternatively be referred to as an adhesion layer.

The total thickness range for the first layer 106, from about 5 nm to about 500 nm, may be significant to subsequent processing steps. The first layer 106 must be sufficiently thick to fully cover the dielectric layer 102 and within the opening 104. If the first layer 106 is discontinuous this layer may not provide sufficient barrier properties between the dielectric layer 102 and the subsequent second layer 108 which can result in reliability issues. Discontinuities in the first layer 106 can also result in poor adhesion between subsequently added layers, including the plated layer. The first layer 106 must be sufficiently thin as to facilitate the eventual removal of a portion of this layer. If the first layer 106 is too thick, removal techniques, such as, wet etching and laser ablation may be affected by etch solution undercut and difficulties fully removing the film, respectively. The first layer 106 must also be sufficiently thin as not to apply stress to the surface of the wafer which may result in wafer bow that makes the wafer difficult to process.

The second layer 108 may be deposited directly on top of the first layer 106, and also within the opening 104, as illustrated. It should be noted that the second layer 108, like the first layer 106, may also include a plurality of layers even though it too is only depicted as a single layer. The second layer 108 may include any low resistance metal suitable for carrying a sufficient electrical current for the subsequent electroplating technique described below. The low resistance metal should be compatible with semiconductor structure fabrication techniques. For example, the second layer 108 may include, but is not limited to, copper (Cu), aluminum (Al), or tungsten (W). In some cases, the second layer 108 may include one or more additives or dopants in addition to the low resistance metal. The additives or dopants may include, such as, for example, manganese (Mn), magnesium (Mg), or combinations thereof. The second layer 108 may have a thickness ranging from about 5 nm to about 1000 nm, and ranges there between, although a thickness of the second layer 108 less than 5 nm or greater than 1000 nm is acceptable. More typically, the second layer 108 may have a thickness ranging from about 100 nm to about 500 nm.

The second layer 108 may be formed using similar techniques as described above with reference to the first layer 106. The second layer 108 may function as a continuous current carrying layer during a subsequent electroplating technique. The second layer 108 may preferably be thick enough to carry a sufficient amount of electrical current to achieve efficient and uniform plating of the interconnect material during the subsequent electroplating technique. It should be noted that the second layer 108 may generally be thicker than the fourth layer 112. To ensure efficient and uniform plating of the interconnect material the thickness of the second layer 108 may preferably be at least about 100 nm. More specifically, the second layer 108 may preferably be at least about 100 nm in order to ensure a sufficient amount of electrical current can be uniformly supplied across the entire structure. The second layer 108 may alternatively be referred to as a current carrying layer.

The total thickness range for the second layer 108, from about 5 nm to about 1000 nm, may be significant to subsequent processing steps. The second layer 108 must be sufficiently thick to fully cover the first layer 106. If the second layer 108 is discontinuous, subsequent electroplating of the interconnect material 114 may be impacted by variations in thickness and/or voids in the plated layer 114. The second layer 108 must also be thick enough to effectively distribute current across the wafer being plated, such that subsequent electroplating of the interconnect material 114 may occur evenly from the edge to the center of the wafer. The second layer 108 must be sufficiently thin as to facilitate the eventual removal of a portion of this layer. If the second layer 108 is too thick, removal techniques, such as, wet etching and laser ablation may be affected by etch solution undercut and difficulties fully removing the film, respectively. The second layer 108 must also be sufficiently thin as not to apply stress to the surface of the wafer which may result in wafer bow that makes the wafer difficult to process.

The third layer 110 may be deposited directly on top of the second layer 108, and also within the opening, as illustrated Like above, the third layer 110 may also include a plurality of layers even though it too is only depicted as a single layer. The third layer 110 may preferably prohibit or inhibit plating of the conductive material during the subsequent electroplating technique. Therefore, the third layer 110 may be constructed from a material that will not allow plating of the interconnect material during the subsequent electroplating technique. In an embodiment, for example, the third layer 108 may include the same or similar material as the first layer 106 described above. The third layer 110 may have a thickness ranging from about 5 nm to about 500 nm, and ranges there between, although a thickness of the third layer 110 less than 5 nm or greater than 500 nm is acceptable. More typically, the third layer 110 may have a thickness ranging from about 50 nm to about 150 nm. In an embodiment, the third layer 110 may preferably remain above and cover the second layer 108. The third layer 110 may be formed using similar techniques as described above with reference to both the first layer 106 and the second layer 108. It should be noted that the third layer 110 may alternatively be referred to as a plate inhibiting layer.

In some embodiments, it may be preferable to fabricate the first layer 106 and the third layer 110 from identical or near identical materials. For example both the first layer 106 and the third layer 110 may be made from a layer of tantalum nitride and a layer of tantalum, or both may be made from titanium tungsten. In other embodiments, it may be preferable to fabricate the first layer 106 and the third layer 110 from different materials. For example, the first layer 106 can be made from a layer of tantalum nitride and a layer of tantalum, and the third layer 110 can be made from titanium tungsten. In another embodiment, any of the layers in the stack of layers made from a tantalum nitride layer followed by a tantalum layer, may alternatively be made from a titanium tungsten layer followed by a titanium layer or vice versa.

The total thickness range for the third layer 110, from about 5 nm to about 500 nm, may be significant to subsequent processing steps. The third layer 110 must be sufficiently thick as to prevent its removal during a subsequent chemical mechanical polishing technique described below. The third layer 110 must be sufficiently thin as to facilitate the eventual removal, limit wafer bow during subsequent processing, and provide good adhesion to underlying metals. If the third layer 110 is too thick, removal techniques, such as, wet etching and laser ablation may be affected by etch solution undercut and difficulties fully removing the film, respectively. The third layer 110 must also be sufficiently thin as not to apply stress to the surface of the wafer which may result in wafer bow that makes the wafer difficult to process.

The fourth layer 112 may be deposited directly on top of the third layer 110, and also within the opening 104 (FIG. 1), as illustrated. Like above, the fourth layer 112 may also include a plurality of layers even though it too is only depicted as a single layer. The fourth layer 112 may preferably function as a seed or foundation on which the interconnect material will be subsequently plated and fill the opening 104 (FIG. 1). In an embodiment, the fourth layer 112 may be substantially similar to the second layer 108 described above. Generally, the material of the fourth layer 112 may match the interconnect material. For example, if a copper interconnect material will be used, the fourth layer 112 may also preferably be copper. In another embodiment, the fourth layer 112 may include additives and dopants similar to those used in the second layer 108. In some embodiments, the second layer 108 and the fourth layer 112 may include the same or different additives or dopants. In other embodiments, the fourth layer 112 may include one or more additives or dopants even though the second layer 108 may include none or vice versa. The fourth layer 112 may have a thickness ranging from about 5 nm to about 1000 nm, and ranges there between, although a thickness of the fourth layer 112 less than 5 nm or greater than 1000 nm is acceptable. More typically, the fourth layer 112 may have a thickness ranging from about 200 nm to about 500 nm. The fourth layer 108 may alternatively be referred to as a plate supporting layer or plate promoting layer.

The total thickness range for the fourth layer 112, from about 5 nm to about 1000 nm, may be significant to subsequent processing steps. If the fourth layer 112 is discontinuous, subsequent electroplating of the interconnect material 114 may be impacted by variations in thickness and/or voids in the plated layer 114. The fourth layer 112 must be sufficiently thick as to remain continuous within the opening 104 after post CMP processing where, some of the fourth layer 112 may be etched. The fourth layer 112 must be sufficiently thin as to minimize the cost of CMP processing, limit wafer bow during subsequent processing, provide good adhesion to underlying metals, and minimize dishing around the opening 104. It should be noted that all the layers (106, 108, 110, 112) are conductive and in direct contact with one another, as illustrated in the figures.

Referring now to FIG. 2, after depositing the stack of layers, a first portion of the fourth layer 112 outside of the opening 104 (FIG. 1) may be removed using any technique known to a person of ordinary skill in the art. For example, a chemical mechanical polishing technique may be used to remove the first portion of the fourth layer 112. The chosen polishing technique may preferably expose the third layer 110 in all areas of the structure 100 except for within the opening 104 (FIG. 1), as illustrated. Therefore, a second portion of the fourth layer 112 may remain along a sidewall and a bottom of the opening 104 (FIG. 1).

Next, the opening 104 (FIG. 1) may be substantially filled with an interconnect material 114 using the electroplating technique referenced above. It should be noted that the interconnect material 114 now illustrated in FIG. 2 is the same interconnect material as referenced above. Standard electroplating techniques known in the art may be performed to fill the opening 104 (FIG. 1) with the interconnect material 114. The interconnect material 114 may include, for example, copper, nickel, or other desired materials used to form a conductive feature. In an embodiment, the interconnect material 114 may include additives and dopants similar to those used in the second layer 108. In some embodiments, the fourth layer 112 and the interconnect material may include the same or different additives or dopants. In other embodiments, the fourth layer 112 may include one or more additives or dopants even though the interconnect material may include none, or vice versa.

In most cases, the electroplating technique may result in some amount of the interconnect material 114 extending above and outside the opening 104 (FIG. 1) as excess or overburden. In such cases, another chemical mechanical polishing technique may be used to remove the excess or overburden interconnect material 114.

In the present embodiment the stack of layers may together function as a cathode for the electroplating technique. More specifically, the fourth layer 112 may function as the cathode or the surface to be plated, and an electrical bias, electrical potential, or negative voltage may be applied to the fourth layer 112 by way of the second and third layers 108, 110. Because the fourth layer 112 is present only within the opening, the second layer 108 may be used as the current carrying layer in which to supply the fourth layer 112 or cathode with the necessary electrical current, hence the reason for describing the stack of layers together as the cathode. In addition to prohibiting plating, the third layer 110 may conduct the electrical current from the second layer 108 to the fourth layer 112. In an embodiment, the electrical current may be applied to the second layer 108 at or near an outermost edge of the structure 100. More specifically, the electrical current may be directly applied to the third layer 110 which is conductive and in direct contact with the second layer 108. Since all layers (106, 108, 110) are conductive, most of the applied current will quickly be passed from the third layer 110 to the continuous neighboring second layer 108 as it provides a lower resistivity path for the electrical current.

While performing the electroplating technique, the third layer 110 and the fourth layer 112 may be in direct contact with an electrolyte solution upon which the interconnect material 114 (e.g., copper) suspended in the electrolyte solution can deposit or plate out on the fourth layer 112 and substantially fill the opening 104 (FIG. 1). While even though the third layer 110 is in direct contact with the electrolyte solution, the interconnect material 114 suspended in the electrolyte solution does not deposit or does not plate out on the third layer 110, as mentioned above. The electrolyte solution may include, but is not limited to, copper sulfate (CuSO₄) or sulfuric acid (H₂SO₄). The electroplating technique may be performed until the interconnect material 114 (e.g., copper) from the electrolyte solution overfills and extends outside of the top opening 104 (FIG. 1). A polishing technique (not shown) may optionally be used to remove any excess interconnect material 114 extending above the top of the opening 104 (FIG. 1).

It should be noted that the thickness of the second layer 108, or current carrying layer, may affect the plating process. As discussed above, a thicker layer may produce more uniform plating across an entire structure, and similarly, a relatively thin current carrying layer may affect plating uniformity across the entire structure.

At the present step, the interconnect material 114 of multiple features across a wafer may remain electrically connected through the second layer 108. Therefore, after plating the interconnect material 114, portions of the stack of layers, for example the first, the second, the third, and the fourth layers 106, 108, 110, 112, may be removed from the structure 100 to purposefully break any electrical connection between multiple features across the wafer. To that end, the portion of the stack of layers may preferably be removed from areas of the structure 100 unrelated to the conductive feature. Stated differently, the portion of the stack of layers may preferably be removed from the structure 100 everywhere there is not a conductive feature.

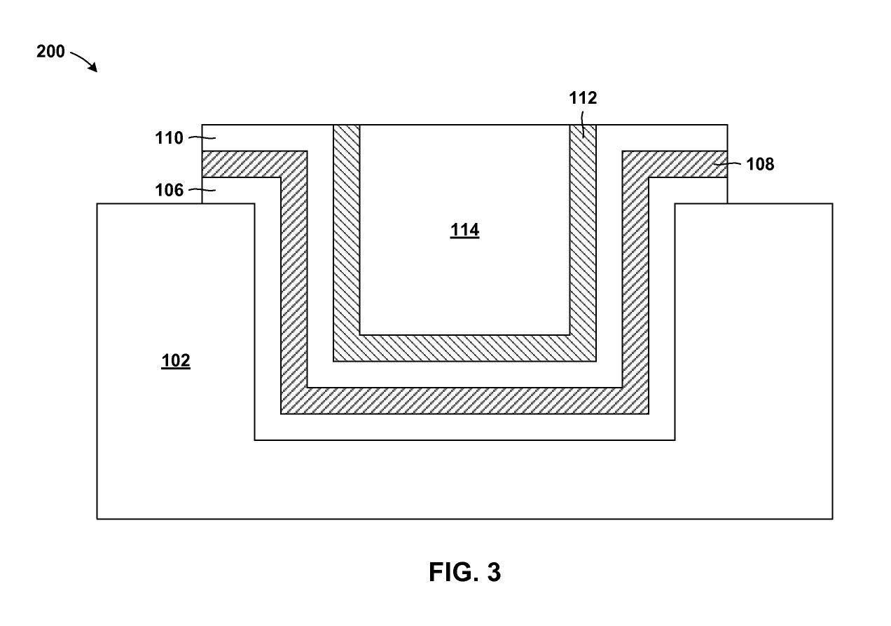

The portion of the stack of layers may be removed from the structure 100 using a variety of removal techniques. The portion of the stack of layers may be remove in multiple steps, one or two layers at a time, or in a single step. The portion of the stack of layer may be removed using any one of a variety of removal techniques, such as, for example, chemical mechanical polishing, dry etching (e.g. RIE), wet etching, or laser ablation. It should be noted that additional details regarding the removal of the portion of the stack of layers is discussed below with reference to alternative embodiments illustrated in FIGS. 3-6.

FIGS. 3-6 illustrate and describe alternative embodiments of the structure 100. Again, each of the figures is a cross section of a portion of a semiconductor wafer and may illustrate a representative conductive feature for purposes of the following description. It should be noted that each alternative embodiment described below and depicted in FIGS. 3-6 may be in addition to and is intended to complement the embodiment described in detail above with reference to FIGS. 1-2.

Referring now to FIG. 3, a structure 200 according to an embodiment of the invention is shown. In the present embodiment, the first layer 106 may include a tantalum nitride layer followed by a tantalum layer (TaN:Ta), the second layer 108 may be made from either copper or manganese doped copper (Cu or CuMn); the third layer 110 may be made from tantalum (Ta); and the fourth layer 112 may be made from either copper or manganese doped copper (Cu or CuMn). Preferably, a sputter deposition technique may be used to deposit the stack of layers.

In the present embodiment, after depositing the stack of layers and filling the opening 104 (FIG. 1) with the interconnect material 114, a laser ablation removal technique may be used to remove a portion of each of the first, the second, and the third layers 106, 108, 110, as illustrated. Any known masking and patterning technique may be used to isolate or define the portion of the stack of layers to be removed by the laser ablation technique. As mentioned above, the portion of each of the first, the second, and the third layers 106, 108, 110 may be removed from everywhere there is not a conductive feature in preparation for subsequent processing.

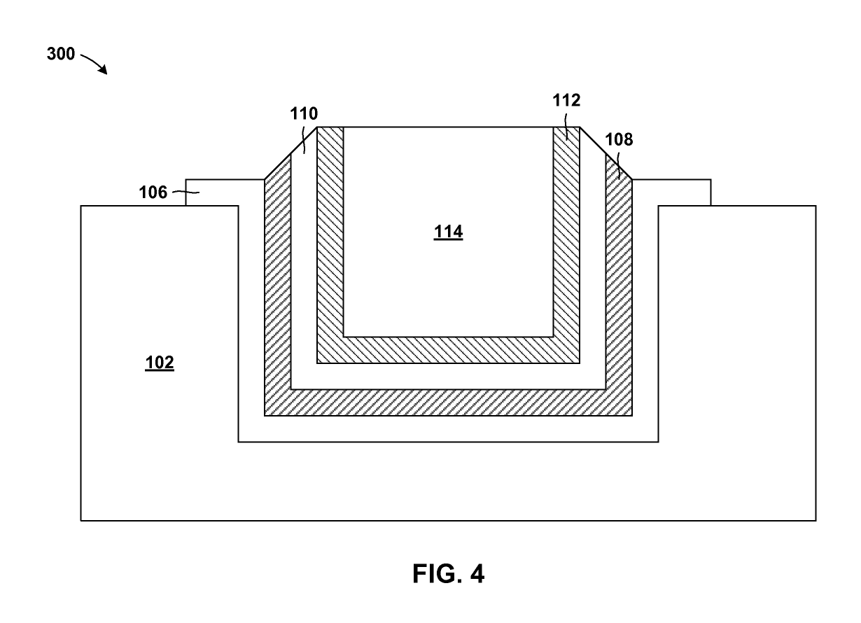

Referring now to FIG. 4, a structure 300 according to an embodiment of the invention is shown. In the present embodiment, the first layer 106 may include a tantalum nitride layer followed by a tantalum layer (TaN:Ta), the second layer 108 may be made from either copper or manganese doped copper (Cu or CuMn); the third layer 110 may be made from titanium tungsten (TiW); and the fourth layer 112 may be made from either copper or manganese doped copper (Cu or CuMn). Preferably, a sputter deposition technique may be used to deposit the stack of layers.

In the present embodiment, after depositing the stack of layers and filling the opening 104 (FIG. 1) with the interconnect material 114, a wet etching technique may be used first to remove a portion of the third layer 110 and second to remove a portion of the second layer 108, as illustrated. Finally, a laser ablation removal technique may be used to remove a portion of the first layer 106, as illustrated. In an alternative embodiment, if the second layer 108 is made from copper or manganese doped copper (Cu or CuMn) and is less than about 250 nm thick, then the laser ablation technique may be used to remove the portion of the first and second layers 106, 108 in a single step.

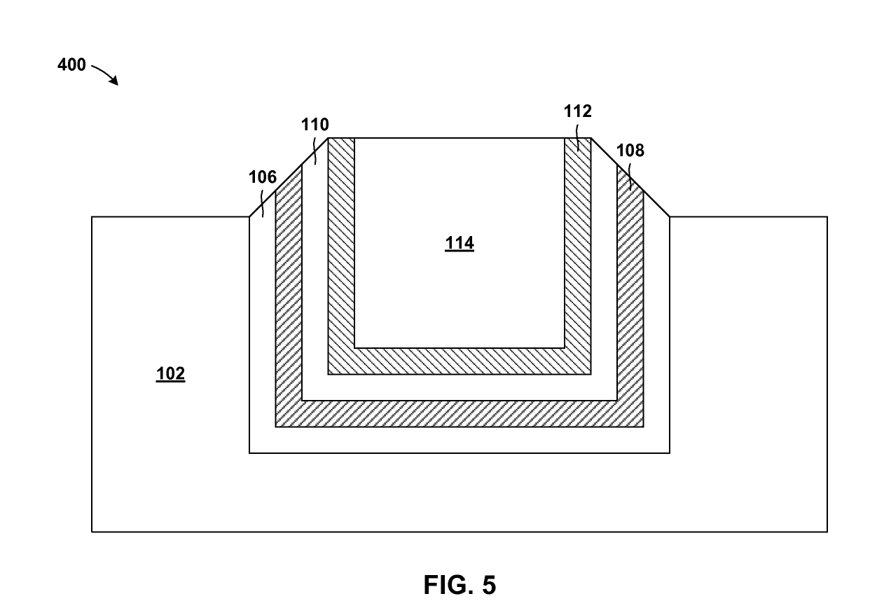

Referring now to FIG. 5, a structure 400 according to an embodiment of the invention is shown. In the present embodiment, the first layer 106 may be made from titanium tungsten (TiW), the second layer 108 may be made from either copper or manganese doped copper (Cu or CuMn); the third layer 110 may be made from titanium tungsten (TiW); and the fourth layer 112 may be made from either copper or manganese doped copper (Cu or CuMn). Preferably, a sputter deposition technique may be used to deposit the stack of layers.

In the present embodiment, after depositing the stack of layers and filling the opening 104 (FIG. 1) with the interconnect material 114, a wet etching technique may be used to remove a portion of the third layer 110, a portion of the second layer 108, and a portion of the first layer 106, as illustrated. Each portion of the portions of the third layer 110, the second layer 108, and the first layer 106 may be removed successively using different etch chemistries.

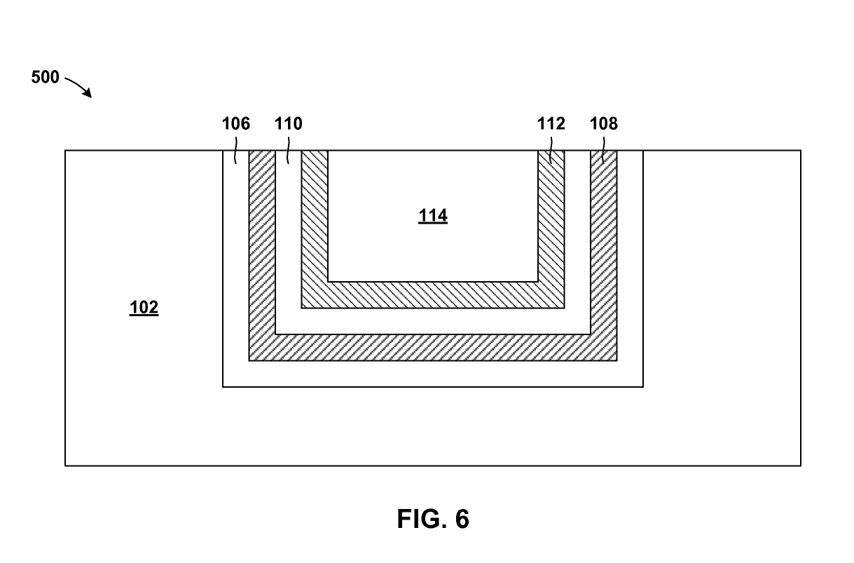

Referring now to FIG. 6, a structure 500 according to an embodiment of the invention is shown. In the present embodiment, the stack of layers may be made from any of those combinations of materials listed above with reference to FIGS. 1-5.

In the present embodiment, after depositing the stack of layers and filling the opening 104 (FIG. 1) with the interconnect material 114, a chemical mechanical polishing technique may be used to remove a portion of the first layer 106, a portion of the second layer 108, a portion of the third layer 110, a portion of the fourth layer 112, and an excess portion of the interconnect material 114, as illustrated. It should be noted that after the chemical mechanical polishing technique, an upper surface of the remaining portions of the first layer 106, the second layer 108, the third layer 110, the fourth layer 112, and the interconnect material 114 may be substantially flush with an upper surface of the dielectric layer 102. Furthermore, each portion of the first layer 106, the second layer 108, the third layer 110, the fourth layer 112, and the interconnect material 114 may be removed successively using different polishing parameters. Alternatively, each portion of the first layer 106, the second layer 108, the third layer 110, the fourth layer 112, and the interconnect material 114 may be removed together using the same polishing parameters.

The embodiments disclosed herein may be particularly unique because a wet etching technique cannot remove some of the above layers, such as, for example, layers made from tantalum. The use of ablation based removal techniques has enabled the use of tantalum based layers and the creation of the multilayered structure disclosed herein. Moreover, performing a chemical mechanical polishing technique on a soft dielectric is often damaging and would no longer be required with the multilayered plating structure disclosed herein.

Integration of the multilayered plating structure into the fabrication of the conductive feature may produce good selectivity and enable uniform plating all while minimizing processing defects, lowering fabrication costs, and improving yield. The embodiments disclosed herein may improve process optimization, prevent extensive overplating, and both enable and limit the use of damascene based plating techniques. Process optimization may be improved by separating different functions into different layers, such as, for example, the barrier function, the current carrying function, the plating inhibiting function, and the plating promoting function. More specifically, the current carrying function and the plate supporting function may now be individually optimized with respect to material choice and layer thickness. Extensive overplating may now be reduced or eliminated because a substantially smaller area of the wafer, about 5%, may be plated as opposed to an entire surface of the wafer. Finally, damascene based plating baths currently limited to features with an aspect ratio of 1:1, depth to width, may now be used for plating features with an aspect ratio of 0.01:1 because plating has been selectively confined to areas where the fourth layer 112 is exposed, for example, where exposed copper is present.

Furthermore, the selective plating technique disclosed herein may eliminate or substantially reduce the need for the removal of heavy overburden of the interconnect material 114 from above the dielectric layer 102 which may potentially cause damage to the dielectric material 102. The embodiments described herein may reduce or eliminate potential damage to the dielectric layer 102, by providing ablation based methods which do not create undercut and prevent scratching related to typical chemical mechanical polishing.

Fabrication costs may be reduced using the above selective plating technique by reducing the amount of leveling agents required in the plating bath. Large amounts of leveling agents may typically be used to inhibit plating of the features on an upper surface of the dielectric layer balanced against a small concentration of an organic that is easily oxidized/reduced. By eliminating the need of a high concentration of leveling agents, higher concentrations of accelerating agents can be used. Even though the rate of oxidation/reduction will still remain the same, the impact of these species relative to the higher concentration of the unaltered accelerating agent, leads to much longer bath life or ability to fill deeper features or both.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A method comprising:
forming a stack of layers on top of a dielectric layer and within an opening in the dielectric layer, the stack of layers comprising a first layer, a second layer, a third layer, and a fourth layer, each formed successively one on top of another;
removing a first portion of the fourth layer outside the opening to expose a portion of the third layer, a second portion of the fourth layer remains within the opening;
filling the opening with a metal by applying an electrical potential to the second layer during an electroplating technique in which the metal plates out on the fourth layer but does not plate out on the third layer; and
removing portions of the first layer, the second layer, and the third layer to expose an upper surface of the dielectric layer between the opening and an adjacent opening.

2. The method of claim 1, wherein the first layer provides mechanical adhesion between the dielectric layer, and the first layer prevents a material of the second layer from diffusing into the dielectric layer.

3. The method of claim 1, wherein the second layer is thick enough to carry enough electrical current to achieve uniform plating results across an entire structure, and the second layer is thicker than the fourth layer.

4. The method of claim 1, further comprising:
polishing the first layer, the second layer, the third layer, the fourth layer, and the metal such that an upper surface of each is substantially flush with an upper surface of the dielectric layer.

5. The method of claim 1, further comprising:
removing any remaining portion of the first layer, the second layer, and the third layer outside of the opening using a laser ablation technique or ion beam etch technique.

6. The method of claim 1, wherein the first and third layers comprise tantalum, tantalum nitride, titanium, titanium nitride, tungsten, titanium tungsten, or some combination thereof.

7. The method of claim 1, wherein the second and fourth layers comprise copper, copper manganese, or some combination thereof.

8. A method comprising:
selectively plating a conductive feature in an opening in a dielectric layer without plating an upper surface of the dielectric layer using a quad layer plating structure comprising a first layer, a second layer, a third layer, and a fourth layer each formed successively one on top of another, the first layer being in direct contact with the dielectric layer.

9. The method of claim 8, where selectively plating the conductive feature in the opening in the dielectric comprises:
selectively plating the conductive feature without using a photoresist or a mask.

10. The method of claim 8, wherein the fourth layer of the quad layer plating structure is located only along a sidewall and a bottom of the opening, and the first layer, the second layer, and the third layer are located on top of an upper surface of the dielectric layer.

11. The method of claim 8, wherein the conductive feature is selectively plated only in the fourth layer and is not plated on the third layer.

12. The method of claim 8, wherein all layers of the quad layer plating structure are removed from the upper surface of the dielectric layer after selectively plating the conductive feature in the opening.

13. The method of claim 8, wherein the first layer provides mechanical adhesion between the dielectric layer and the second layer, and the first layer prevents a material of the second layer from diffusing into the dielectric layer.

14. The method of claim 8, wherein each of the first layer, the second layer, the third layer, and the fourth layer are each deposited successively one on top of another using a sputter depositing technique.

15. The method of claim 8, wherein selectively plating the conductive feature in the opening comprises:
exposing the opening, including the fourth layer, to an electrolyte solution; and
applying an electrical potential to the second layer, the electrical potential conducts through the third layer from the second layer to the fourth layer.

16. A structure comprising:
a stack of conformal layers on top of a dielectric layer and within an opening in the dielectric layer, the stack of layers comprising a first layer, a second layer, a third layer, and a fourth layer, each formed successively one on top of another with the first layer being in direct contact with the dielectric layer; and
a conductive feature located directly on top of the fourth layer within the opening.

17. The structure of claim 16, wherein the first layer provides mechanical adhesion between the dielectric layer and the second layer, and the first layer prevents a material of the second layer from diffusing into the dielectric layer.

18. The structure of claim 16, wherein the second layer is thick enough to carry enough electrical current to achieve uniform plating results across an entire structure, and the second layer is thicker than the fourth layer.

19. The structure of claim 16, wherein an upper surface of each of the first layer, the second layer, the third layer, the fourth layer, and the conductive feature are substantially flush with an upper surface of the dielectric layer.

20. The structure of claim 16, wherein the first and third layers comprise tantalum, tantalum nitride, titanium, titanium nitride, tungsten, titanium tungsten, or some combination thereof, and wherein the second and fourth layers comprise copper, copper manganese, or some combination thereof.
